(19) United States
(12) Patent Application Publication
(10) Pub. No.: US 2026/0282858 A1
(43) Pub. Date: Sep. 17, 2026

(54) SELECTIVE RUTHENIUM REMOVAL BY MICROWAVE OXIDATION PLASMA

(71) Applicant: Applied Materials, Inc., Santa Clara, CA (US)

(72) Inventors: Mohammad Mahdi TAVAKOLI, Santa Clara, CA (US); Joung Joo LEE, San Jose, CA (US)

(21) Appl. No.: 19/169,254

(22) Filed: Apr. 3, 2025

(51) Int. Cl. H10W 20/00; C23C 16/455; C23C 16/52; H10P 14/40; H10P 14/43; H10P 50/26

(52) U.S. Cl. CPC H10W 20/0595; C23C 16/45544; C23C 16/52; H10P 14/412; H10P 14/43; H10P 50/267

(57) ABSTRACT

Methods and apparatus for forming semiconductor devices, and more specifically to methods for filling ruthenium features for forming low resistivity electrical connections. In one aspect, a method of forming a film on a semiconductor substrate is provided. The method includes a cyclic deposition-etch process. The cyclic deposition-etch process includes depositing a ruthenium layer over a bottom surface and sidewall surfaces that define an opening of a feature. The cyclic deposition-etch process further includes trimming the ruthenium layer by exposing the ruthenium layer to microwave radiation to remove at least a first portion of the ruthenium layer formed over the sidewall surfaces. The method further includes bottom-up growth of ruthenium from the ruthenium layer formed over the bottom surface.

### BACKGROUND

### Field

Embodiments of the present disclosure generally relate to methods and apparatus for forming semiconductor devices, and more specifically to methods for filling ruthenium features for forming low resistivity electrical connections.

### Description of the Related Art

Integrated circuits have evolved into complex devices that can include billions of transistors, capacitors, and resistors on a single chip. In the course of integrated circuit evolution, functional density, that is, the number of interconnected devices per chip area, has generally increased while geometry size, that is, the smallest component (or line) that can be created using a fabrication process, has decreased.

Microelectronic devices are fabricated on a semiconductor substrate as integrated circuits in which various conductive layers are interconnected with one another to permit electronic signals to propagate within the device. Examples of such devices include memory, for example, dynamic random access memory (DRAM) and logic devices, including both planar and three-dimensional structures. Three-dimensional structures include fin field-effect transistor (finFET) or metal-oxide-semiconductor field-effect transistor (MOSFET) devices.

Traditional middle-end-of-the-line (MEOL) electrical connections are formed in a feature, also referred to as a via, a trench, an opening, or the like, in the semiconductor substrate. MEOL electrical connections allow connections between front-end-of-the-line (FEOL) semiconductor structures and back-end-of-the-line (BEOL) interconnects. Electrical connections with a low resistivity are desirable in semiconductor devices. However, when MEOL electrical connections have high resistance, the electrical connections produce poor connections between the FEOL structures and the BEOL interconnects, reducing the performance of the packaged semiconductor structures. For example, MEOL electrical connections may have a resistivity due to seams present in the electrical connection, for example, seams formed in the conductive material deposited in the feature to form the electrical connection.

Reliable electrical connections with a low resistivity are desirable in semiconductor manufacturing.

Thus, there is a need for methods and systems for forming reliable electrical with low resistivity in semiconductor devices.

### SUMMARY

Embodiments of the present disclosure generally relate to methods and apparatus for forming semiconductor devices, and more specifically to methods for filling ruthenium features for forming low resistivity electrical connections.

In one aspect, a method of forming a film on a semiconductor substrate is provided. The method includes a cyclic deposition-etch process. The cyclic deposition-etch process includes depositing a ruthenium layer over a bottom surface and sidewall surfaces that define an opening of a feature. The cyclic deposition-etch process further includes trimming the ruthenium layer by exposing the ruthenium layer to microwave radiation to remove at least a first portion of the ruthenium layer formed over the sidewall surfaces. The method further includes bottom-up growth of ruthenium from the ruthenium layer formed over the bottom surface.

Embodiments may include one or more of the following. The ruthenium layer is exposed to a microwave plasma. The ruthenium layer is not exposed to a plasma. The sidewall surfaces include a low-k dielectric material and the bottom surface comprises a metal material. The method further includes exposing the ruthenium layer to a gas flow while exposing the ruthenium layer to microwave radiation. The gas flow and the microwave radiation are continuous. The gas flow includes an oxygen-containing gas. The oxygen-containing gas is supplied at a flow rate in a range from about 20 sccm to about 300 sccm. The semiconductor substrate is maintained at a temperature in a range from about 75° C. to about 150° C. The bottom-up growth of ruthenium includes repeating the cyclic deposition-etch process until the ruthenium achieves a targeted thickness.

In another aspect, a method of forming a film on a semiconductor substrate is provided. The method includes a cyclic deposition-etch process. The cyclic deposition-etch process includes depositing a ruthenium layer over a bottom surface and sidewall surfaces that define an opening of a feature. Depositing the ruthenium layer comprises sequential exposure of the semiconductor substrate to an iodine-containing reactant, a purge gas, an organometallic precursor, and the purge gas. The cyclic deposition-etch process further includes trimming the ruthenium layer by exposing the ruthenium layer to a microwave plasma to remove at least a first portion of the ruthenium layer formed over the sidewall surfaces. The method further includes bottom-up growth of ruthenium from the ruthenium layer formed over the bottom surface.

Embodiments may include one or more of the following. The ruthenium layer is exposed to a microwave plasma. The ruthenium layer is not exposed to a plasma. The sidewall surfaces include a low-k dielectric material and the bottom surface comprises a metal material. The method further includes exposing the ruthenium layer to a gas flow while exposing the ruthenium layer to microwave radiation. The gas flow and the microwave radiation are continuous. The gas flow includes an oxygen-containing gas. The oxygen-containing gas is supplied at a flow rate in a range from about 20 sccm to about 300 sccm. The semiconductor substrate is maintained at a temperature in a range from about 75° C. to about 150° C. The bottom-up growth of ruthenium includes repeating the cyclic deposition-etch process until the ruthenium achieves a targeted thickness.

In yet another aspect, a processing system is provided. The processing system includes a first processing region, a second processing region, and a system controller. The system controller includes a memory for storing computer readable instructions and a processor coupled to the memory, the processor configured by the computer readable instructions that when executed by the processor perform a plurality of operations. The operations include a cyclic deposition-etch process. The cyclic deposition-etch process includes depositing a ruthenium layer over a bottom surface and sidewall surfaces that define an opening of a feature on a semiconductor substrate in the first processing region, transferring the semiconductor substrate from the first processing region to the second processing region, and trimming the ruthenium layer by exposing the ruthenium layer to microwave radiation to remove at least a first portion of the ruthenium layer formed over the sidewall surfaces. The plurality of operations further include bottom-up growth of ruthenium from the ruthenium layer formed over the bottom surface.

Embodiments may include one or more of the following. The ruthenium layer is exposed to a microwave plasma. The ruthenium layer is not exposed to a plasma. The sidewall surfaces include a low-k dielectric material and the bottom surface comprises a metal material. The method further includes exposing the ruthenium layer to a gas flow while exposing the ruthenium layer to microwave radiation. The gas flow and the microwave radiation are continuous. The gas flow includes an oxygen-containing gas. The oxygen-containing gas is supplied at a flow rate in a range from about 20 sccm to about 300 sccm. The semiconductor substrate is maintained at a temperature in a range from about 75° C. to about 150° C. The bottom-up growth of ruthenium includes repeating the cyclic deposition-etch process until the ruthenium achieves a targeted thickness.

In yet another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a process flow diagram of a method of forming a ruthenium feature in a semiconductor structure in accordance with one or more embodiments of the present disclosure.

FIGS. 2A-2D illustrate cross-sectional views of a portion of a semiconductor structure corresponding to various stages of the method of FIG. 1 in accordance with one or more embodiments of the present disclosure.

FIG. 3 illustrates a schematic top view of a multi-chamber processing system in accordance with one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments disclosed herein generally relate to methods for forming low resistivity contacts for semiconductor device formation. In a traditional contact junction formation process, a feature also referred to as a cavity, a via, or a trench, is fabricated in the semiconductor substrate. In one example, middle-of-the-line (MOL) contact junctions allow connections between front-end-of-the-line (FEOL) semiconductor structures and back-end-of-the-line (BEOL) interconnects. However, when MOL contacts have high resistance, the contacts produce poor connections between the FEOL structures and the BEOL packaging interconnects, reducing the performance of the packaged semiconductor structures. Thus, electrical connections, for example, contacts and interconnects, with a low resistivity are desirable in semiconductor devices.

Ruthenium is one type of metal used to form electrical connections. Ruthenium precursors typically have low selectivity meaning that ruthenium can be deposited on both metal surfaces and dielectric surfaces. The low selectivity of ruthenium precursors makes bottom-up growth challenging leading to the formation of gaps or seams in the deposited ruthenium film, which increases the resistivity of the deposited ruthenium film making ruthenium undesirable for electrical connections. In order to achieve seam-free or substantially seam-free ruthenium film deposition, the selectivity of ruthenium precursors needs to be improved.

In one or more embodiments, a cyclic deposition-etch process is provided. The cyclic deposition-etch process includes a deposition process in which a ruthenium layer is formed over a bottom surface and sidewall surfaces that define an opening of a feature. The sidewall surfaces can include a low-k dielectric material and the bottom surface can include a metal material. The deposition process can include sequential exposure of the surfaces of the feature to an iodine-containing reactant, a purge gas, an organometallic precursor, and the purge gas to deposit the ruthenium layer. Multiple cycles of the deposition process can be performed to deposit the ruthenium layer. The cyclic deposition-etch process further includes an etching process that includes removing a portion of the ruthenium layer formed over the sidewall surfaces. The etching process can include microwave plasma oxidation of the ruthenium layer formed over the sidewall surfaces. Multiple cycles of the cyclic deposition-etch process may be performed to remove the ruthenium layer from the sidewall surfaces while a portion of the ruthenium layer formed over the bottom surface remains forming a ruthenium seed layer along the bottom surface. Bottom-up growth of ruthenium from the ruthenium seed layer formed over the bottom surface is then performed to provide seam-free ruthenium fill of the feature.

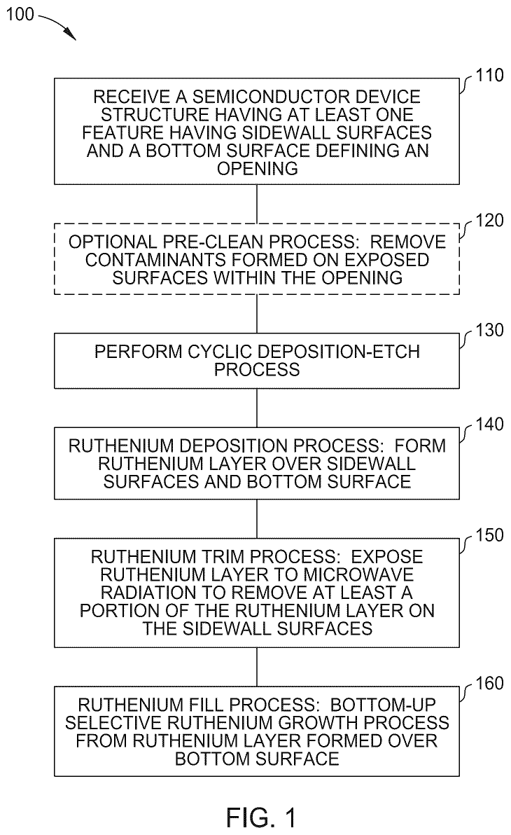

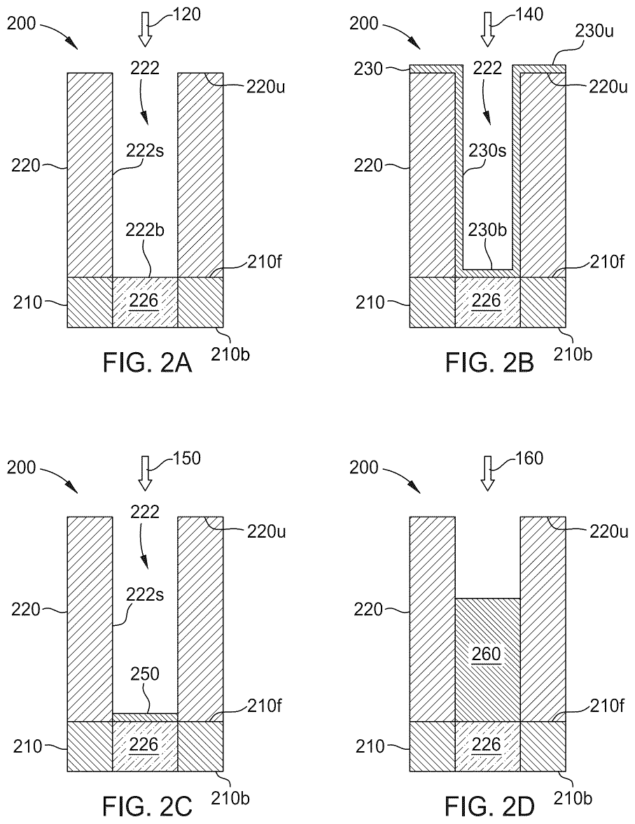

FIG. 1 illustrates a process flow diagram of a method 100 of forming a ruthenium feature in a semiconductor structure in accordance with one or more embodiments of the present disclosure. FIGS. 2A-2D illustrate cross-sectional views of a portion of a semiconductor device structure 200 corresponding to various stages of the method 100 of FIG. 1 in accordance with one or more embodiments of the present disclosure. With reference to FIGS. 2A-2D, schematic views of the semiconductor device structure 200 at various stages of manufacture are provided to illustrate the method of FIG. 2. Although FIGS. 2A-2D are described in relation to the method 100, it will be appreciated that the structures disclosed in FIGS. 2A-2D are not limited to the method 100, but instead may stand alone as structures independent of the method 100. Similarly, although the method 100 is described in relation to FIGS. 2A-2D, it will be appreciated that the method 100 is not limited to the structures disclosed in FIGS. 2A-2D, but instead may stand alone independent of the structures disclosed in FIGS. 2A-2D. It should also be noted that although the method 100 illustrated in FIG. 1 is described sequentially, other process sequences that include one or more operations that have been omitted and/or added, and/or have been rearranged in another desirable order, fall within the scope of the embodiments of the disclosure provided herein.

Referring to FIG. 2A, at operation 110, a semiconductor device structure 200 having at least one feature 222 is received. The semiconductor device structure 200 includes a device substrate 210 having one or more layers formed thereon, for example, a dielectric layer 220 as is shown in FIG. 2A. The device substrate 210 has a frontside 210f (also referred to as a front surface) and a backside 210b (also referred to as a back surface) opposite the frontside 210f. The device substrate can include an electrical connection 226. The dielectric layer 220 is formed over the frontside 210f of the device substrate 210. The dielectric layer 220 may include multiple layers, for example, the dielectric layer can include low-k dielectric materials, high-k dielectric materials, and/or etch stop materials. The dielectric layer 220 includes an upper surface 220u or field region. In some embodiments, the dielectric layer 220 includes silicon oxide, silicon oxynitride, silicon nitride, a combination thereof, or multi-layers thereof. In some embodiments, the dielectric layer 220 consists essentially of silicon oxide. It is noted that the foregoing descriptors (e.g., silicon oxide) should not be interpreted to disclose any particular stoichiometric ratio. Accordingly, “silicon oxide” and the like will be understood by one skilled in the art as a material consisting essentially of silicon and nitrogen without disclosing any specific stoichiometric ratio.

The device substrate 210 may be or include a bulk semiconductor substrate, a semiconductor-on-insulator (SOI) substrate, or the like, which may be doped, for example, with a p-type dopant or an n-type dopant, or undoped. In some embodiments, the semiconductor material of the device substrate 210 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AlInAs, GaInAs, GaInP, and/or GaInAsP; a combination thereof, or the like. The device substrate 210 may include additional materials, for example, silicide layers, metal silicide layers, metal layers, dielectric layers, etch stop layers, interlayer dielectrics, or a combination thereof. The device substrate 210 may further include integrated circuit devices (not shown). As one of ordinary skill in the art will recognize, a wide variety of integrated circuit devices such as transistors, diodes, capacitors, resistors, the like, or combinations thereof may be formed in and/or on the device substrate 210 to generate the structural and functional requirements of the design for the resulting semiconductor device structure 200.

The dielectric layer 220 is patterned to form one or more feature(s) 222. The feature 222 can also be referred to as a cavity, via, trench, or opening. The feature 222 may be a high aspect ratio (HAR) feature. In some embodiments, the feature 222 can be selected from a trench, a via, a hole, or combinations thereof. In particular embodiments the feature 222 is a trench. In some embodiments, the feature 222 extends from the upper surface 220u of the dielectric layer 220 to the frontside 210f of the device substrate 210. The feature 222 includes sidewall surface(s) 222s and a bottom surface 222b extending between the sidewall surface(s) 222s, which define an opening. In some embodiments, the sidewall surface(s) 222s is tapered. The sidewall surface(s) 222s may be defined by the dielectric layer 220 and the bottom surface 222b may be defined by the electrical connection 226, for example, a conductive material. In some embodiments, the sidewall surface(s) 222s may be defined by the dielectric layer 220 and the bottom surface may also be defined by the dielectric layer 220 or a silicon-containing material. The feature 222 has a first depth “D1” from the upper surface 220u to the bottom surface 222b and a width “W1” between the two sidewall surface(s) 222s.

In some embodiments, an electrical connection, such as the electrical connection 226 is formed within the feature 222. The electrical connection 226 may be an interconnect, a contact structure, or the like. The electrical connection 226 may be formed by depositing a conductive material into the feature 222. The conductive material may be deposited such that the conductive material fills the entire feature 222 or at least a portion of the feature 222. For example, as shown in FIG. 2A, the electrical connection 226 may be an interconnect or a contact structure formed by filling a bottom portion of the feature 222 with a conductive material. In some embodiments, the bottom portion is defined by (extends between) the frontside 210f and the backside 210b of the device substrate 210. Therefore, the electrical connection 226 may extend between the frontside 210f and the backside 210b of the device substrate 210 (or any other portion of the feature 222, including the entire feature 222). The electrical connection 226 may comprises any suitable conductive material or metal. The conductive material or metal may be formed of copper (Cu), cobalt (Co), molybdenum (Mo), tungsten (W), ruthenium (Ru), or a combination thereof.

The feature 222 has a first depth “D1” from the upper surface 220u to the backside 210b and a width “W1” between the two sidewall surface(s) 222s. In one or more embodiments, the feature 222 or cavity can have an average width. In some embodiments, the width W1 is in a range of 10 nm to 100 nm. For example, the feature 222 can have a width “W1” (shown in FIG. 2A) of about 35 nanometers (nm) or less, such as about 5 nm to about 35 nm, such as about 5 nm, 10 nm, and 15 nm to about 20 nm, 25 nm, 30 nm, or 35 nm. In some embodiments, the depth D1 is in a range of 2 nm to 200 nm. In some embodiments, the feature 222 can have an aspect ratio (depth:width) in a range of about 1:1 to about 100:1, such as about 10:1, 15:1, or 25:1 to about 35:1, 45:1, or 50:1. Without being bound by theory, the present methods allow for the deposition of a ruthenium gapfill material having no and/or reduced seams within the gapfill material.

In some embodiments, one or more barrier layers are formed on or over the sidewall surface(s) of the feature 222 prior to deposition of the ruthenium layer 230. The barrier layer may serve to prevent diffusion of a subsequently deposited metal layer into adjacent layers, for example, the dielectric layer 220. The barrier layer can include any material suitable to perform as a barrier. In some embodiments, the barrier layer includes a metal, for example, titanium (Ti), Tantalum (Ta), cobalt (Co), manganese (Mn), tungsten (W), hafnium (Hf), alloys thereof, or the like, or in some embodiments, a metal nitride, such as titanium nitride (TiN), tantalum nitride (TaN), tungsten nitride (WN), or the like.

Referring to FIG. 2A, optionally at operation 120, a pre-clean process is performed to remove contaminants, such as native oxides, from the exposed surfaces within the feature 222, for example, the sidewall surface(s) 222s, the bottom surface 222b, and the upper surface 220u. In one or more embodiments, the pre-clean process to remove oxide-containing contaminants may include an isotropic etch process, such as a wet etch process using distilled hydrofluoric acid (d-HF) solution, or a dry chemical etch process using ammonia (NH₃) and nitrogen trifluoride (NF3), for example a thermal etch using NH3 and NF3 or a plasma etch using a plasma formed from NH3, NF3, and HF. The etch process is selective for oxide layers, and thus does not readily etch silicon, germanium, or nitride layers regardless of whether the layers are amorphous, crystalline or polycrystalline. Selectivity of the etch process for oxide versus silicon or germanium is at least about 3:1, and usually 5:1 or better, sometimes 10:1. In one or more other embodiments, the pre-clean process to remove oxide-containing contaminants may include an anisotropic remote plasma assisted dry etch process, such as a reactive ion etching (RIE) process, using a plasma formed from a gas including hydrogen (H), argon (Ar), helium (He), or a combination thereof. In one or more other embodiments, the pre-clean process includes exposing the electrical connection 226 to microwaves to remove impurities and reduce the resistivity of the electrical connection 226. The microwaves can have a frequency in a range from about 330 MHz to about 1000 GHz at a power in a range from about 100 to about 500 W for a time period in a range from about 3 minutes to about 30 minutes in a processing chamber maintained at a temperature in a range from about 300 to about 450° C. and at a pressure in a range from about 50 mTorr to about 500 mTorr.

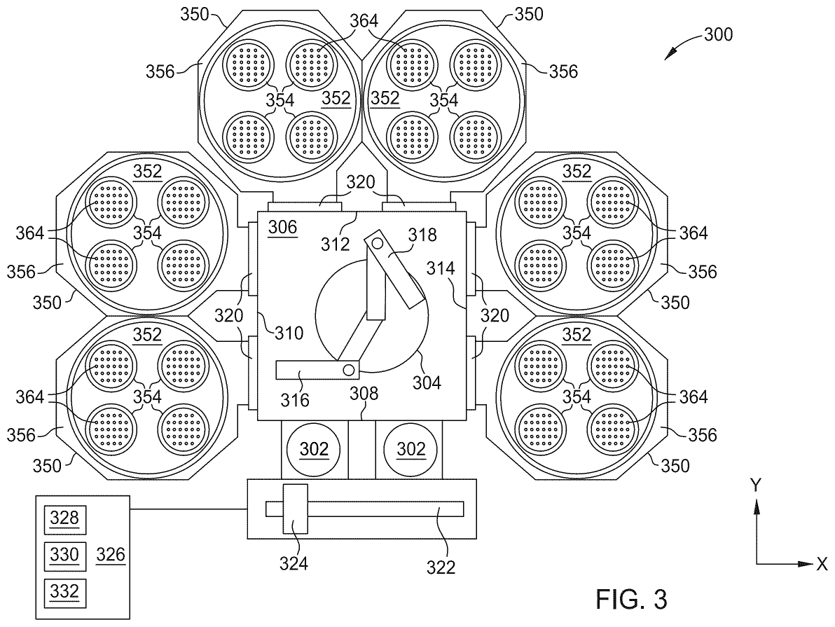

At operation 130, a cyclic deposition-etch process is performed to selectively form a ruthenium seed layer 250 on the surface of the electrical connection 226 as shown in FIG. 3C. The cyclic deposition-etch process includes a ruthenium deposition process to deposit a ruthenium layer 230 at operation 130 followed by a ruthenium trim process to remove unwanted portions of the ruthenium layer 230 to form the ruthenium seed layer 250. The cyclic deposition-etch process can be repeated any number of times until the ruthenium seed layer 250 achieves a targeted thickness.

Referring to FIG. 2B, at operation 140, a ruthenium deposition process is performed. The ruthenium deposition process includes forming a ruthenium layer 230 on the exposed surfaces defining the feature 222, for example, the sidewall surface(s) 222s, the bottom surface 222b, and the upper surface 220u. The ruthenium deposition process of operation 140 includes a bottom portion 230b formed on the bottom surface 222b, a sidewall portion 230s formed on the sidewall surface(s) 222s, and an upper portion 230u formed on the upper surface 220u or field region. During operation 140, as shown in FIG. 2B, a deposition process is performed to form the ruthenium layer 230 on or over the sidewall surface(s) 222s, the bottom surface 222b, and the upper surface 220u of the feature 222.

The ruthenium deposition process of operation 140 can provide a thickness of the ruthenium layer 230 of approximately 1 nm to approximately 10 nm on the sidewall surface(s) 222s, the bottom surface 222b, and/or the upper surface 220u. In some embodiments, the thickness of the ruthenium layer 230 is conformal along the sidewall surface(s) 222s and/or the bottom surface 222b. In some embodiments, the thickness of the sidewall portion 230s of the ruthenium layer 230 formed on the sidewall surface(s) is less than a thickness of the bottom portion 230b of the ruthenium layer 230 formed on the bottom surface 222b.

The ruthenium deposition during operation 140 can be performed using any suitable thermal or plasma enhanced CVD, PVD, or ALD processes. In some embodiments, the CVD or ALD process includes utilizing a plasma that includes precursors. A carrier gas may be utilized in the CVD or ALD process. The plasma/carrier gas may then be introduced towards the surface of the semiconductor substrate. In one or more embodiments, the carrier gas includes a noble gas, such as argon, neon, helium, or combinations thereof.

In one or more embodiments, deposition of the ruthenium layer 230 during operation 140 is performed in a process cycle including sequential exposure of the semiconductor device structure 200 to an iodine-containing reactant, purge gas, organometallic ruthenium precursor, purge gas, and optionally a reductant. Any number of process cycles may be performed until the ruthenium layer 230 achieves a targeted thickness. In one or more embodiments, between 5 and 20 process cycles or between 10 and 15 process cycles are performed.

The iodine-containing reactant can be any suitable iodine-containing compound that can react with (i.e., adsorb or chemisorb onto) the substrate surface to leave an iodine-containing species on the substrate surface. In one or more embodiments, the iodine-containing reactant includes a species having a formula RIₓ, where R is one or more of a C₁-C₁₀ alkyl, cycloalkyl, alkenyl, or alkynyl group and x is in a range of 1 to 4. In one or more embodiments, R comprises one or more of a methyl, ethyl, n-propyl, isopropyl, n-butyl, s-butyl, t-butyl, n-pentyl, s-pentyl, t-pentyl, hexyl, or a cyclohexyl group. In one or more embodiments, I is monoiodo (I) or diiodo (I₂). In one or more embodiments, the iodine-containing reactant comprises diiodomethane (CH₂I₂).

During operation 140, the processing chamber is optionally purged to remove unreacted iodine-containing reactant, reaction products and by-products. In one or more embodiments, the purge gas is selected from one or more of nitrogen (N₂), helium (He), and argon (Ar). In one or more embodiments, operation 140 includes flowing at least 200 sccm of the purge gas. In one or more embodiments, the substrate surface is purged of the iodine-containing reactant prior to exposing the substrate to a ruthenium organometallic precursor.

The ruthenium-containing reactant can be any suitable ruthenium organometallic precursor that can react with the iodine-containing species on the substrate surface to from the ruthenium layer 230.

During operation 140, the processing chamber may be optionally purged after exposure to the ruthenium organometallic precursor. The carbon-less ruthenium-containing film is optionally exposed to a reductant, for example, hydrogen gas (H2).

In one or more embodiments, the deposition process of operation 140 is performed by maintaining the semiconductor substrate at a deposition temperature. In one or more embodiments, the process is conducted at a temperature in a range of from 150° C. to 600° C., or in the range of 200° C. to 550° C., or in the range of 250° C. to 500° C., or in the range of 300° C. to 450° C. In one or more embodiments, the process is conducted at a pressure in a range of 0.1 Torr to 20 Torr.

Referring to FIG. 2C, at operation 150, a ruthenium trim process is performed. The ruthenium trim process includes removing at least a portion of the ruthenium layer 230, for example, the sidewall portion 230s and/or the upper portion 230u of the ruthenium layer 230, exposing at least a portion of the underlying materials, for example, the sidewall surface(s) 222s of the dielectric layer 220. The ruthenium trim process of operation 150 includes exposing the ruthenium layer 230 to microwave radiation. In some embodiments, the microwave process does not generate a reactive plasma. Stated another way, in some embodiments, the ruthenium layer 230 is not exposed to a plasma. In other embodiments, the microwave process generates a reactive plasma such that the ruthenium layer 230 is exposed to a reactive plasma.

In one or more embodiments, the microwave process includes exposing the ruthenium layer 230 to a gas flow while exposing the ruthenium layer to microwave radiation. In some embodiments, the gas flow and the microwave radiation can be continuous meaning that neither the gas flow nor the microwave sources are pulsed during the microwave process. In other embodiments, the microwave sources and the gas flow are pulsed.

In one or more embodiments, the gas flow comprises, consists of, or consists essentially of an oxygen-containing gas. The oxygen-containing gas can be oxygen (O2), ozone (O3), or a combination thereof. The oxygen gas can be supplied at a flow rate in a range from about 20 sccm to about 300 sccm. The oxygen-containing gas can form an oxygen-containing plasma including one or more of oxygen ions, oxygen radicals, or oxygen neutrals. In one or more embodiments, the gas flow comprises, consists of, or consists essentially of hydrogen (H2). In one or more embodiments, the gas flow comprises, consists of, or consists essentially of oxygen and hydrogen. In one or more embodiments, the gas flow comprises, consists of, or consists essentially of an inert gas. The inert gas can include helium, argon, or both helium and argon. In one or more embodiments, the gas flow includes both an oxygen-containing gas and an inert gas. Not to be bound by theory but it is believed that the oxygen-containing gas or the oxygen-containing plasma reacts with the sidewall portion 230s of the ruthenium layer and/or the upper portion 230u of the ruthenium layer 230 to form RuO4, which can be purged from the processing volume.

In some embodiments, operation 150 is performed at relatively low temperatures. The relatively low temperatures advantageously result in decreased damage to surrounding materials (e.g., dielectrics). In some embodiments, the metal material is maintained at temperature in a range from about 300° C. to about 300° C. In some embodiments, the metal material is maintained at a temperature of less than or equal to about 300° C. In some embodiments, the metal material is maintained at temperature in a range from about 50° C. to about 200° C., or in a range from about 75° C. to about 150° C., or in a range from about 100° C. to about 125° C.

In some embodiments, the period of exposure is controlled to reduce a predetermined depth of the ruthenium layer 230. In some embodiments, the period is in a range of about 60 seconds to about 600 seconds, in a range of about 100 seconds to about 300 seconds, or in a range of about 100 seconds to about 200 seconds.

In some embodiments, the power of the microwave source is in a range of about 50 W to about 1000 W, or in a range of about 100 W to about 500 W, or in a range of about 100 W to about 150 W.

In some embodiments, the pressure of the processing volume may be controlled. In some embodiments, the pressure is maintained in a range of about 1 mTorr to about 10 Torr, or in a range of about 10 mTorr to about 1 Torr, or in a range of about 30 mTorr to about 1 Torr. In some embodiments where operation 150 includes a non-plasma microwave process, the pressure is maintained at or equal to 15 mTorr or below, for example, in a range from about 1 mTorr to about 15 mTorr. In some embodiments where operation 150 includes a plasma microwave process, the pressure is maintained at or equal to 30 mTorr or above, for example, in a range from about 30 mTorr to about 1 Torr.

In some embodiments where the microwave process generates a reactive oxygen plasma, the oxygen plasma gradually removes the ruthenium layer 230 from the dielectric layer 220. The oxygen plasma etches or “trims” the ruthenium layer 230. In one or more embodiments, at least a portion of the ruthenium layer 230 is etched away from the dielectric layer 220 such that at least a portion of the ruthenium layer 230 remains on the electrical connection 226. For example, the oxygen plasma removes at least the sidewall portion 230s and/or the upper portion 230u of the ruthenium layer 230 from the dielectric material, exposing the sidewall surface(s) 222s and/or the upper surface 220u of the dielectric material while the bottom portion 230b of the ruthenium layer 230 remains forming the ruthenium seed layer 250 on the bottom surface 222b of the feature 222, which is defined by the top surface of the electrical connection 226 as shown in FIG. 2C. The microwave oxygen plasma has a lower ion energy and a higher ion density when compared with comparable ICP oxygen plasmas and CCP oxygen plasmas. Thus, the microwave oxygen plasma provides less damage to dielectric materials while achieving improved performance.

Referring to FIG. 2D, at operation 160, a metal gapfill material process is performed. The metal gapfill process includes bottom-up selective growth of a metal gapfill material 260 from the ruthenium seed layer 250. The metal gapfill material 260 may partially or fully fill the feature 222. The metal gapfill material 260 is shown in contact with the ruthenium seed layer 250 and the bottom surface 222b of the feature 222. The metal gapfill material 260 is also in contact with at least a portion of the sidewall surface(s) 222s. The metal gapfill process can be done by selective ruthenium fill or conformal ruthenium fill.

In one or more embodiments, the metal gapfill process includes repeating the cyclic deposition-etch process until the metal gapfill material 260 achieves a targeted thickness.

Any suitable chemical deposition process, including but not limited to CVD or ALD processes, may be utilized for the metal gapfill material process of operation 160. The metal gapfill material 260 may be applied such that the metal gapfill material is grown on the ruthenium seed layer 250 along the bottom surface 222b of the feature 222 and then grown upwards towards the semiconductor field region, for example, the upper surface 220u of the feature 222, that the resultant gapfill material at least approaches the field region (as shown in FIG. 2D) or is at least partially level with the field region (not shown).

In one or more embodiments, the metal gapfill material 260 includes one or more of cobalt (Co), molybdenum (Mo), tungsten (W), tantalum (Ta), titanium (Ti), ruthenium (Ru), rhodium (Rh), copper (Cu), iron (Fe), manganese (Mn), vanadium (V), niobium (Nb), hafnium (Hf), zirconium (Zr), yttrium (Y), aluminum (Al), tin (Sn), chromium (Cr), lanthanum (La), iridium (Ir), or any combination thereof. In one or more particular embodiments, the metal gapfill material 260 includes ruthenium.

After a cycle of the deposition process, one or more cycles can be repeated with an optional purge between cycles, until a targeted thickness of the metal gapfill material 260 is achieved. During the purge, a purge gas, which can be argon (Ar), is introduced in the processing chamber. In some embodiments, the purge gas includes hydrogen (H₂) gas.

FIG. 3 illustrates a schematic top view of a multi-chamber processing platform 300 in accordance with one or more embodiments of the present disclosure. The multi-chamber processing platform 300 can be used for forming low resistivity electrical connections without breaking vacuum in accordance with one or more embodiments of the present disclosure. The processing platform 300 generally includes a factory interface 322 for loading substrates into the processing platform 300, one or more buffer stations 302 coupled to the factory interface 322, a central transfer station 306 with a robot 304, and one or more processing chambers 350. As detailed herein, substrates in the processing platform 300 can be processed in and transferred between the various chambers without exposing the substrates to an ambient environment exterior to the processing platform 300 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing platform 300. Accordingly, the processing platform 300 may provide for an integrated solution for some processing of substrates. The embodiment shown in FIG. 3 is merely representative of one possible configuration and should not be taken as limiting the scope of the disclosure. For example, in some embodiments, the multi-chamber processing platform 300 has a different number of one or more of the processing chambers 350, buffer stations 302 and/or robot 304 configurations than the illustrated embodiment.

Examples of a processing system that may be suitably modified in accordance with the teachings provided herein include the Endura®, Producer®, Centris®, or Centura® integrated processing systems or other suitable processing systems commercially available from Applied Materials, Inc., located in Santa Clara, California. It is contemplated that other processing systems (including those from other manufacturers) may be adapted to benefit from aspects described herein.

The processing chamber 350 has a housing 356 that defines an interior volume 352. The processing chamber 350 includes a plurality of processing stations 354. The processing stations 354 are spatially separated and isolated from each other in the interior volume 352 of the housing 356. The processing stations 354 are positioned in a circular arrangement around a rotational axis of a heater support assembly. The heater support assembly is rotatable such that the wafer can be transferred between processing stations 354. Each processing station 354 independently has a processing chamber temperature that can be different from the other processing station temperatures. The processing stations 354 are defined as a region in which processing can occur. For example, a processing station 354 can be defined by a substrate support surface 364 and a ceiling, for example, a front face of gas injectors and/or a microwave source array.

The processing stations 354 can be configured to perform any suitable process and provide any suitable process conditions. For example, a processing station 354 can be configured to operate as a vapor deposition apparatus for performing a ruthenium deposition process, for example, the ruthenium deposition process of operation 140. Whereas, another processing station 354 can be configured to operate as a microwave processing apparatus configured to emit high-frequency electromagnetic radiation, for example, frequencies in a range from about 300 MHz and 1000 GHz, in the form of microwave energy for performing a ruthenium trim process, for example, the ruthenium trim process of operation 150. Suitable processing stations 354 include, but are not limited to, a vapor deposition station, a microwave plasma station, an inductively coupled plasma (ICP) process station, a capacitively coupled plasma (CCP) process station, an etch soak process station, a thermal process station, a UV exposure station, a laser process station, a pumping chamber station, an annealing station, and a metrology station.

The exemplary processing platform 300 includes a central transfer station 306 which has a plurality of sides 308, 310, 312, 314. The central transfer station 306 shown has a first side 308, a second side 310, a third side 312 and a fourth side 314. Although four sides are shown, those skilled in the art will understand that there can be any suitable number of sides to the central transfer station 306 depending on, for example, the overall configuration of the processing platform 300. In some embodiments, the transfer station 306 has three sides, four sides, five sides, six sides, seven sides or eight sides.

The transfer station 306 has a robot 304 positioned therein. The robot 304 can be any suitable robot capable of moving a wafer during processing. In some embodiments, the robot 304 has a first arm 316 and a second arm 318. The first arm 316 and the second arm 318 can be moved independently of the other arm. The first arm 316 and the second arm 318 can move in the X-Y plane and/or along the Z-axis. In some embodiments, the robot 304 includes a third arm (not shown) or a fourth arm (not shown). Each of the arms can move independently of other arms.

The embodiment illustrated includes six processing chambers 350 with two connected to each of the second side 310, third side 312, and fourth side 314 of the central transfer station 306. Each of the processing chambers 350 can be configured to perform different processes.

The processing platform 300 can also include the one or more buffer station 302 connected to the first side 308 of the central transfer station 306. The buffer stations 302 can perform the same or different functions. For example, the buffer stations 302 may hold a cassette of wafers which are processed and returned to the original cassette, or one of the buffer stations 302 may hold unprocessed wafers which are moved to the other buffer station 302 after processing. In some embodiments, one or more of the buffer stations 302 are configured to pre-treat, pre-heat or clean the wafers before and/or after processing.

The processing platform 300 may also include one or more slit valves 320 between the central transfer station 306 and any of the processing chambers 350. The slit valves 320 can open and close to isolate the interior volume 352 within the processing chamber 350 from the environment within the central transfer station 306. For example, if the processing chamber 350 generates plasma during processing, it may be helpful to close the slit valve 320 for that processing chamber 350 to prevent stray plasma from damaging the robot 304 in the central transfer station 306.

The processing platform 300 can be connected to a factory interface 322 to allow wafers or cassettes of wafers to be loaded into the processing platform 300. A robot 324 within the factory interface 322 can be used to move the wafers or cassettes into and out of the buffer stations. The wafers or cassettes can be moved within the processing platform 300 by the robot 304 in the central transfer station 306. In some embodiments, the factory interface 322 is the central transfer station of another cluster tool, for example, another multiple chamber processing platform.

A system controller 326 may be provided and coupled to various components of the processing platform 300 to control the operation thereof. The system controller 326 can be a single controller that controls the entire processing platform 300, or multiple controllers that control individual portions of the processing platform 300. For example, the processing platform 300 may include separate controllers for each of the individual processing chambers 350, the central transfer station 306, the factory interface 322 and the robots 304.

In some embodiments, the system controller 326 includes a central processing unit (CPU) 328, a memory 330, and support circuits 332. The system controller 326 may control the processing platform 300 directly, or via computers (or controllers) associated with particular process chamber and/or support system components.

The system controller 326 may be one of any form of general-purpose computer processor that can be used in an industrial setting for controlling various chambers and sub-processors. The memory 330 or computer readable medium of the system controller 326 may be one or more of readily available memory such as random access memory (RAM), read only memory (ROM), floppy disk, hard disk, optical storage media (e.g., compact disc or digital video disc), flash drive, or any other form of digital storage, local or remote. The memory 330 can retain an instruction set that is operable by the processor (CPU 328) to control parameters and components of the processing platform 300.

The support circuits 332 are coupled to the CPU 328 for supporting the processor in a conventional manner. These circuits include cache, power supplies, clock circuits, input/output circuitry and subsystems, and the like. One or more processes may be stored in the memory 330 as software routine that, when executed or invoked by the processor, causes the processor to control the operation of the processing platform 300 or individual processing chambers in the manner described herein. The software routine may also be stored and/or executed by a second CPU (not shown) that is remotely located from the hardware being controlled by the CPU 328.

Some or all of the processes and methods of the present disclosure may also be performed in hardware. As such, the process may be implemented in software and executed using a computer system, in hardware as, e.g., an application specific integrated circuit or other type of hardware embodiment, or as a combination of software and hardware. The software routine, when executed by the processor, transforms the general purpose computer into a specific purpose computer (controller) that controls the chamber operation such that the processes are performed.

In some embodiments, the system controller 326 has one or more configurations to execute individual processes or sub-processes to perform the method 100. The system controller 326 can be connected to and configured to operate intermediate components to perform the functions of the methods. For example, the system controller 326 can be connected to and configured to control one or more of gas valves, actuators, motors, slit valves, vacuum control or other components.

Processes, for example, one or more of operations 110-160, may generally be stored in the memory of the system controller 326 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, for example, an application specific integrated circuit or other type of hardware embodiment, or as a combination of software and hardware. The software routine, when executed by the processor, transforms the general-purpose computer into a specific purpose computer (controller) that controls the chamber operation such that the processes are performed.

The previously described embodiments of the present disclosure have many advantages. In one or more embodiments of the present disclosure, deposition of a multi-layer epitaxial source/drain material is performed. The low selectivity of ruthenium precursors makes bottom-up growth challenging leading to the formation of gaps or seams in the deposited ruthenium film, which increases the resistivity of the deposited ruthenium film making ruthenium undesirable for electrical connections. The selectivity of ruthenium precursors is improved by a microwave plasma oxidation process, which removes ruthenium from feature sidewalls while a ruthenium seed layer remains on the bottom surface of the feature. Seam-free or substantially seam-free bottom-up growth is achieved using the ruthenium seed layer. In addition, the microwave oxygen plasma has a lower ion energy and a higher ion density when compared with comparable ICP oxygen plasmas and CCP oxygen plasmas. Thus, the microwave oxygen plasma provides less damage to dielectric materials while achieving improved performance. However, the present disclosure does not necessitate that all the advantageous features and all the advantages need to be incorporated into every embodiment of the present disclosure.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, embodiment, embodiment, or example of the present disclosure, or a particular claim, that feature can also be used, to the extent possible in combination with and/or in the context of other particular aspects and embodiments of the present disclosure, and in the present disclosure generally.

Embodiments and all of the functional operations described in this specification can be implemented in digital electronic circuitry, or in computer software, firmware, or hardware, including the structural means disclosed in this specification and structural equivalents thereof, or in combinations of them. Embodiments described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or embodiment(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to embodiments of the present disclosure, other and further embodiments of the disclosure may be devised without departing from the basic scope thereof, and the scope thereof is determined by the claims that follow.

What is claimed is:

1. A method of forming a film on a semiconductor substrate, comprising:
a cyclic deposition-etch process, comprising:
depositing a ruthenium layer over a bottom surface and sidewall surfaces that define an opening of a feature; and
trimming the ruthenium layer by exposing the ruthenium layer to microwave radiation to remove at least a first portion of the ruthenium layer formed over the sidewall surfaces; and
bottom-up growth of ruthenium from the ruthenium layer formed over the bottom surface.

2. The method of claim 1, wherein the ruthenium layer is exposed to a microwave plasma.

3. The method of claim 1, wherein the ruthenium layer is not exposed to a plasma.

4. The method of claim 1, wherein the sidewall surfaces comprise a low-k dielectric material and the bottom surface comprises a metal material.

5. The method of claim 1, further comprising exposing the ruthenium layer to a gas flow while exposing the ruthenium layer to microwave radiation.

6. The method of claim 5, wherein the gas flow and the microwave radiation are continuous.

7. The method of claim 5, wherein the gas flow comprises an oxygen-containing gas.

8. The method of claim 7, wherein the oxygen-containing gas is supplied at a flow rate in a range from about 20 sccm to about 300 sccm.

9. The method of claim 1, wherein the semiconductor substrate is maintained at a temperature in a range from about 75° C. to about 150° C.

10. A method of forming a film on a semiconductor substrate, comprising:
a cyclic deposition-etch process, comprising:
depositing a ruthenium layer over a bottom surface and sidewall surfaces that define an opening of a feature, wherein depositing the ruthenium layer comprises sequential exposure of the semiconductor substrate to an iodine-containing reactant, a purge gas, an organometallic precursor, and the purge gas; and
trimming the ruthenium layer by exposing the ruthenium layer to a microwave plasma to remove at least a first portion of the ruthenium layer formed over the sidewall surfaces; and
bottom-up growth of ruthenium from the ruthenium layer formed over the bottom surface.

11. The method of claim 10, wherein the sidewall surfaces comprise a low-k dielectric material and the bottom surface comprises a metal material.

12. The method of claim 10, further comprising exposing the ruthenium layer to a gas flow while exposing the ruthenium layer to the microwave plasma.

13. The method of claim 12, wherein the gas flow comprises an oxygen-containing gas.

14. The method of claim 13, wherein the oxygen-containing gas is supplied at a flow rate in a range from about 20 sccm to about 300 sccm.

15. The method of claim 10, wherein the semiconductor substrate is maintained at a temperature in a range from about 75° C. to about 150° C.

16. A processing system, comprising:
a first processing region;
a second processing region; and
a system controller, comprising:
a memory for storing computer readable instructions; and
a processor coupled to the memory, the processor configured by the computer readable instructions that when executed by the processor perform a plurality of operations, comprising:
a cyclic deposition-etch process, comprising:
depositing a ruthenium layer over a bottom surface and sidewall surfaces that define an opening of a feature on a semiconductor substrate in the first processing region;
transferring the semiconductor substrate from the first processing region to the second processing region; and
trimming the ruthenium layer by exposing the ruthenium layer to microwave radiation to remove at least a first portion of the ruthenium layer formed over the sidewall surfaces; and
bottom-up growth of ruthenium from the ruthenium layer formed over the bottom surface.

17. The processing system of claim 16, wherein the ruthenium layer is exposed to a microwave plasma.

18. The processing system of claim 16, wherein the ruthenium layer is not exposed to a plasma.

19. The processing system of claim 16, wherein the sidewall surfaces comprise a low-k dielectric material and the bottom surface comprises a metal material.

20. The processing system of claim 16, further comprising exposing the ruthenium layer to an oxygen-containing gas flow while exposing the ruthenium layer to microwave radiation.
